(19) United States
(12) Patent Application Publication
(10) Pub. No.: US 2024/0096674 A1
(43) Pub. Date: Mar. 21, 2024

(54) CONTAINER RELAY UNIT AND LOGISTICS TRANSPORT SYSTEM INCLUDING THE SAME

(71) Applicant: SEMES CO., LTD., Chungcheongnam-do (KR)

(72) Inventor: Myeong Jin BANG, Chungcheongnam-do (KR)

(21) Appl. No.: 18/225,133

(22) Filed: Jul. 23, 2023

(30) Foreign Application Priority Data
Sep. 20, 2022 (KR) 10-2022-0118256

(51) Int. Cl. H01L 21/677; B65G 47/90

(52) U.S. Cl. CPC H01L 21/6773; B65G 47/90; H01L 21/67733; H01L 21/67772

(57) ABSTRACT

A container relay unit relaying containers between a transport vehicle and load ports and a logistics transport system including the container relay unit are provided. The logistics transport system includes: a container transport unit installed in a semiconductor fabrication plant, the container transport unit transporting containers loaded with semiconductor substrates; a load port unit where the containers are loaded or unloaded; semiconductor fabrication equipment connected to the load port unit, the semiconductor fabrication equipment processing the semiconductor substrates loaded in the containers; and a container relay unit relaying the containers between the container transport unit and the load port unit, wherein the container relay unit is installed on the same level as a moving path of the container transport unit, on a level above the load port unit.

### CROSS-REFERENCE TO RELATED APPLICATION

This application claims priority from Korean Patent Application No. 10-2022-0118256 filed on Sep. 20, 2022 in the Korean Intellectual Property Office, and all the benefits accruing therefrom under 35 U.S.C. 119, the contents of which in its entirety are herein incorporated by reference.

### BACKGROUND

### 1. Field

The present disclosure relates to a container relay unit and a logistics transport system including the same, and more particularly, to a container relay unit associated with the transport of containers with semiconductor substrates loaded therein in a semiconductor fabrication plant and a logistics transport system including the container relay unit.

### 2. DESCRIPTION OF THE RELATED ART

Wafers used to fabricate semiconductor devices may be subject to various processes in a semiconductor fabrication plant (commonly called a “fab”), and may be transported to process facilities. For example, a plurality of wafers may be loaded in a container such as a front opening unified pod (FOUP), the container may be transported to a process facility by a transport vehicle such as an overhead hoist transport (OHT), which is movably provided at the ceiling of a semiconductor fabrication plant.

A transport vehicle may continue to carry multiple containers within a semiconductor fabrication plant. For example, the transport vehicle may transport a first container to destination A and then a second container to destination B.

When arriving at destination A, the transport vehicle may load the first container on a load port such as an equipment front end module (EFEM), using a hoist. Thereafter, the transport vehicle moves to where the second container is located to transport the second container B to destination B.

Thus, the transport vehicle cannot move to where the second container is located before transporting the first container to the load port at destination A, and if problems occur in the process of transporting the first container to the load port at destination A, the transport of the second container may be considerably delayed.

### SUMMARY

Aspects of the present disclosure provide a container relay unit capable of relaying containers between transport vehicles and load ports and a logistics transport system including the container relay unit.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a logistics transport system includes: a container transport unit installed in a semiconductor fabrication plant, the container transport unit transporting containers loaded with semiconductor substrates; a load port unit where the containers are loaded or unloaded; semiconductor fabrication equipment connected to the load port unit, the semiconductor fabrication equipment processing the semiconductor substrates loaded in the containers; and a container relay unit relaying the containers between the container transport unit and the load port unit, wherein the container relay unit is installed on the same level as a moving path of the container transport unit, on a level above the load port unit.

According to another aspect of the present disclosure, a logistics transport system includes: a container transport unit installed in a semiconductor fabrication plant, the container transport unit transporting containers loaded with semiconductor substrates; a load port unit where the containers are loaded or unloaded; semiconductor fabrication equipment connected to the load port unit, the semiconductor fabrication equipment processing the semiconductor substrates loaded in the container; and a container relay unit relaying the containers between the container transport unit and the load port unit, wherein the container relay unit includes a robot arm, which picks up the containers from the container transport unit, a storage module, which temporarily stores the containers, and a lifting module, which delivers the containers to the load port unit, the container relay unit is installed on the same level as a moving path of the container transport unit, on a level above the load port unit, the container relay unit communicates with at least one of the container transport unit and the load port unit, and if the container relay unit is able to relay the containers, the container transport unit delivers the containers directly to the load port unit.

According to another aspect of the present disclosure, a container relay unit relaying containers between a container transport unit, which transports containers loaded with semiconductor substrates, in a semiconductor fabrication plant, and a load port unit where the containers is loaded or unloaded, is provided. The container relay unit includes: a robot arm picking up the containers from the container transport unit; a storage module temporarily storing the containers; and a lifting module delivering the containers to the load port unit.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram of a logistics transport system according to an embodiment of the present disclosure;

FIG. 2 illustrates an exemplary layout of the elements of the logistics transport system of FIG. 1;

FIG. 3 illustrates the inner structure of a container transport unit of the logistics transport system of FIG. 1;

FIG. 4 illustrates how the container transport unit of FIG. 3 is installed in a semiconductor fabrication plant;

FIG. 5 illustrates an exemplary layout of a load port unit of the logistics transport system of FIG. 1 and semiconductor fabrication equipment;

FIG. 6 illustrates another exemplary layout of the load port unit of the logistics transport system of FIG. 1 and the semiconductor fabrication equipment;

FIG. 7 illustrates another exemplary layout of the load port unit of the logistics transport system of FIG. 1 and the semiconductor fabrication equipment;

FIG. 8 illustrates the benefits of a logistics transport system with a container relay unit provided therein;

FIG. 9 illustrates the inner structure of the container relay;

FIG. 10 illustrates an exemplary lifting module of the container relay unit;

FIG. 11 illustrates another exemplary lifting module of the container relay unit;

FIG. 12 illustrates another exemplary layout of the elements of the logistics transport system of FIG. 1;

FIG. 13 illustrates the inner structure of a side track buffer (STB) of the logistics transport system of FIG. 1;

FIG. 14 illustrates an exemplary operating principle of a door of the STB;

FIG. 15 illustrates another exemplary operating principle of the door of the STB;

FIG. 16 illustrates another exemplary layout of the elements of the logistics transport system;

FIG. 17 illustrates another exemplary layout of the elements of the logistics transport system of FIG. 1; and

FIG. 18 illustrates another exemplary layout of the elements of the logistics transport system of FIG. 1.

### DETAILED DESCRIPTION

Embodiments of the present disclosure will hereinafter be described with reference to the attached drawings. Like reference numerals indicate like elements throughout the specification and drawings.

The present disclosure relates to a logistics transport system for transporting containers with semiconductor substrates loaded therein in a semiconductor fabrication plant. The logistics transport system may include a container relay unit, which relays containers between transport vehicles and load ports. The logistics transport system and the container relay unit will hereinafter be described.

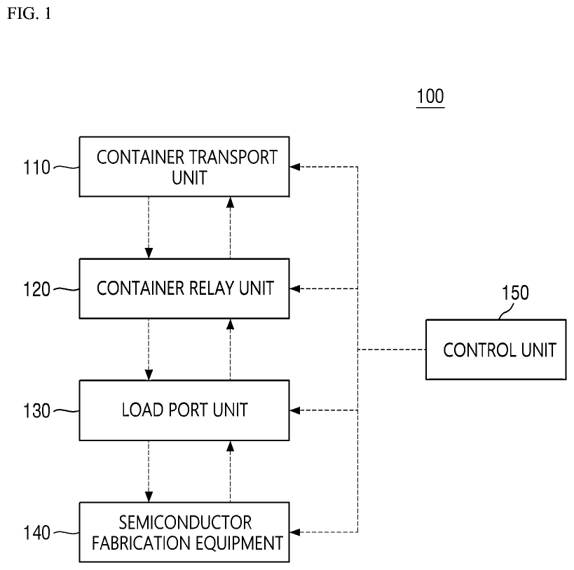

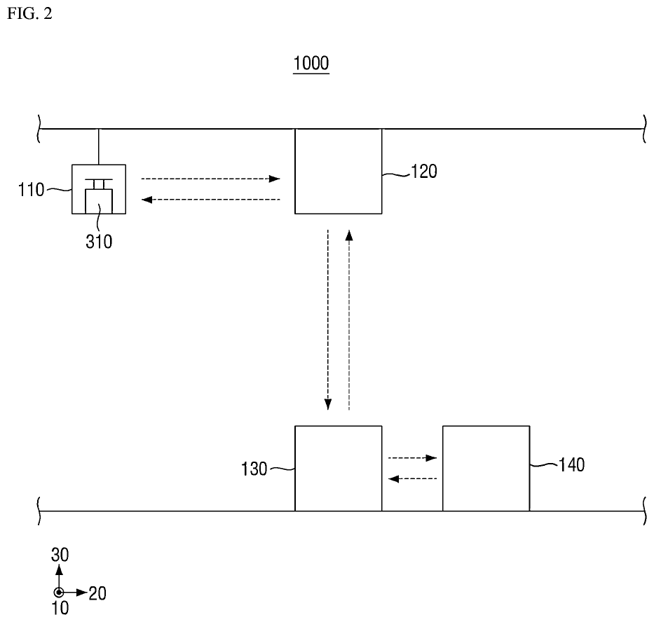

FIG. 1 is a block diagram of a logistics transport system according to an embodiment of the present disclosure. FIG. 2 illustrates an exemplary layout of the elements of the logistics transport system of FIG. 1.

Referring to FIGS. 1 and 2, a logistics transport system 100 may include a container transport unit 110, a container relay unit 120, a load port unit 130, semiconductor fabrication equipment 140, and a control unit 150. The logistics transport system 100 may be used to provide a logistics automation service in a semiconductor fabrication plant 1000.

The container transport unit 110 may transport a container 310 to a particular destination. The container transport unit 110 may be provided as, for example, an overhead hoist transport (OHT).

The container transport unit 110 may transport the container 310 to the particular destination, traveling along a moving path (e.g., a rail) installed at the ceiling of the semiconductor fabrication plant 1000. The container transport unit 110 may transport the container 310 to equipment where semiconductor fabrication processes are performed, i.e., to the semiconductor fabrication equipment 140. A plurality of container transport units 110 may be disposed in the semiconductor fabrication plant 1000.

In a case where the container transport unit 110 transports the container 310 to the semiconductor fabrication equipment 140, a plurality of semiconductor substrates may be loaded in the container 310. The container 310 may be provided as, for example, a Front Opening Unified Pod (FOUP), and the semiconductor substrates may be, for example, wafers.

The container transport unit 110 may operate under the control of the control unit 150. Although not specifically illustrated in FIG. 1, the container transport unit 110 may include a communication module for communicating with the control unit 150 in a wired or wireless manner.

The container transport unit 110 may operate autonomously without being controlled by the control unit 150. In this case, a plurality of sensors may be installed on the moving path of the container transport unit 110 to prevent the container transport unit 110 from colliding with other container transport units 110, in the semiconductor fabrication plant 1000, and the container transport unit 110 may share information with other container transport units 110 via the sensors. Alternatively, the container transport unit 110 may be configured to be able to communicate with other container transport units 110.

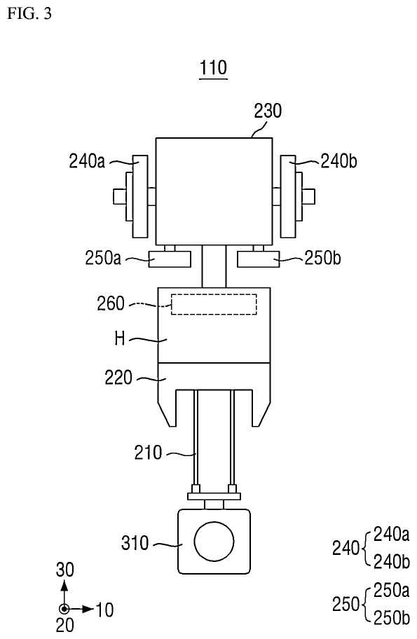

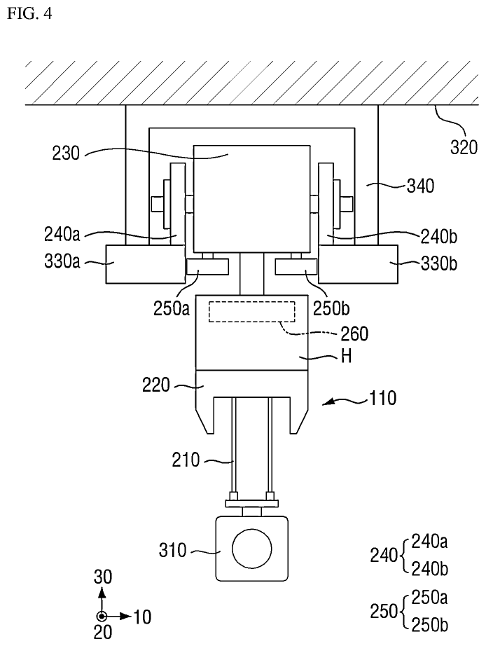

FIG. 3 illustrates the inner structure of the container transport unit of the logistics transport system of FIG. 1. FIG. 4 illustrates how the container transport unit of FIG. 3 is installed in a semiconductor fabrication plant.

Referring to FIGS. 3 and 4, the container transport unit 110 may include a gripping module 210, an elevation module 220, a driving module 230, driving wheels 240, guide wheels 250, and a control module 260.

The gripping module 210 is provided to grip a container 310. The gripping module 210 may be lifted down to where the container 310 is located (i.e., to the load port unit 130) to grip the container 310. The gripping module 210 may be provided as, for example, a hand gripper.

The elevation module 220 is provided to lift up or down the gripping module 210. The elevation module 220 may lift down the gripping module 210 in a direction from a ceiling 320 of the semiconductor fabrication plant 1000 to the ground to grip the container 310, and may lift up the gripping module 210 to the ceiling 320 of the semiconductor fabrication plant 1000 once the gripping module 210 grips the container 310. The elevation module 220 may be provided as, for example, a hoist.

Once the container 310 is loaded by the gripping module 210 and the elevation module 220, the container transport unit 110 may transport the container 310 to its destination. When the container transport unit 110 arrives at the destination, the elevation module 220 lifts down the gripping module 210 again, and the gripping module 210 loads the container 310 on the load port unit 130 and then releases the grip of the container 310.

Although not specifically illustrated in FIGS. 3 and 4, the container transport unit 110 may include a storage module, which provides storage space, instead of the gripping module 210. The storage module may be formed in a shape with an open top, for example, in a basket shape, or in a shape with a door on a side thereof, for example, in a cabinet shape, to load the container 310 therein.

The driving module 230 may control the driving wheels 240, which travel along the moving route (e.g., a pair of rails 330a and 330b) installed at the ceiling 320 of the semiconductor fabrication plant 1000. Although not specifically illustrated in FIGS. 2 and 3, the driving module 230 may include a driving motor and a driving shaft. The driving motor may generate a driving force, and the driving shaft may provide the driving force to the driving wheels 240.

The driving wheels 240, which rotate with a driving force provided by the driving module 230, allow the container transport unit 110 to travel along the rails 330a and 330b. A pair of driving wheels 240, i.e., driving wheels 240a and 240b, may be provided to travel along the rails 330a and 330b, respectively, in which case, the driving wheels 240a and 240b may be coupled to both sides of the driving module 230.

The guide wheels 250 prevents the container transport unit 110 from deviating from the rails 330a and 330b while driving along the rails 330a and 330b. A pair of guide wheels 250, i.e., guide wheels 250a and 250b, may be provided and may be installed at both ends of the bottom surface of the driving module 230, perpendicularly to the driving wheels 240a and 240b.

The control module 260 controls the other modules of the container transport unit 110. The control module 260 may control the operation of the gripping module 210 and the elevation module 220 and may also control the operation of the driving motor of the driving module 230. Although not specifically illustrated in FIGS. 2 and 3, the control module 260 may include a front frame and a rear frame and may support the gripping module 210 and the elevation module 220, which are coupled to the bottom surface of the control module 260. The control module 260 may be provided as, for example, an OHT controller.

Although not specifically illustrated in FIGS. 2 and 3, the control module 260 may include a speed controller and a position controller. The speed controller may control the rotation speed of the driving wheels 240, and the position controller may adjust the position of the container 310.

The position controller may include a slider and a rotator. The slider may move the container 310 in a vertical direction or in a horizontal direction, and the rotator may rotate the container 310 clockwise or counterclockwise.

To provide a moving route for the container transport unit 110, a rail assembly including the rails 330a and 330b and a rail support module 340 may be installed at the ceiling 320 of the semiconductor fabrication plant 1000. The rails 330a and 330b, which provide a driving route for the container transport unit 110, may be coupled to both ends of the rail support module 340, which is fixed onto the ceiling 320 of the semiconductor fabrication plant 1000.

The rails 330a and 330b may include various types of sections such as rectilinear sections, curved sections, inclined sections, branch sections, and crossing sections, but the present disclosure is not limited thereto. The rails 330a and 330b may be configured to include sections of only one type.

The rail support module 340 is fixed to the ceiling 320 of the semiconductor fabrication plant 1000 and supports the rails 330a and 330b. The rail support module 340 may be installed at the ceiling 320 of the semiconductor fabrication plant 1000 to have a cap shape, as viewed from the ground.

Referring again to FIGS. 1 and 2, the container 310 is loaded in, or unloaded from, the load port unit 130. Also, the semiconductor substrates loaded in the container 310 may also be loaded in, or unloaded from, the load port unit 130.

The container 310 may be loaded in, or unloaded from, the load port unit 130 by the container transport unit 110. As already mentioned above, the container 310 may be loaded in the load port unit 130 by placing the container 310 on the load port unit 130 via the container transport unit 110, and may be unloaded from the load port unit 130 by gripping the container 310 from the load port unit 130 via the container transport unit 110.

The semiconductor wafers in the container 310 may be loaded in, or unloaded from, the load port unit 130 by the semiconductor fabrication equipment 140. When the container 310 is loaded in the load port unit 130, a substrate transport robot of the semiconductor fabrication equipment 140 may approach the load port unit 130 and may retrieve the semiconductor substrates from the container 310. Once the processing of the semiconductor substrates in the semiconductor fabrication equipment 140 is complete, the substrate transport robot retrieves the semiconductor substrates from the semiconductor fabrication equipment 140 and loads the semiconductor substrates back in the container 310.

The semiconductor fabrication equipment 140 processes the semiconductor substrates. The semiconductor fabrication equipment 140 may be installed near the load port unit 130 to process the semiconductor substrates loaded in the container 310. The load port unit 130 may be provided at the end of a front end module (FEM) such as an equipment FEM (EFEM).

The semiconductor fabrication equipment 140 may include chambers of the same type or of different types, such as a chamber for performing a deposition process, a chamber for performing an etching process, a chamber for performing a cleaning process, and a chamber for performing a heat treatment process. The semiconductor fabrication equipment 140 will hereinafter be described.

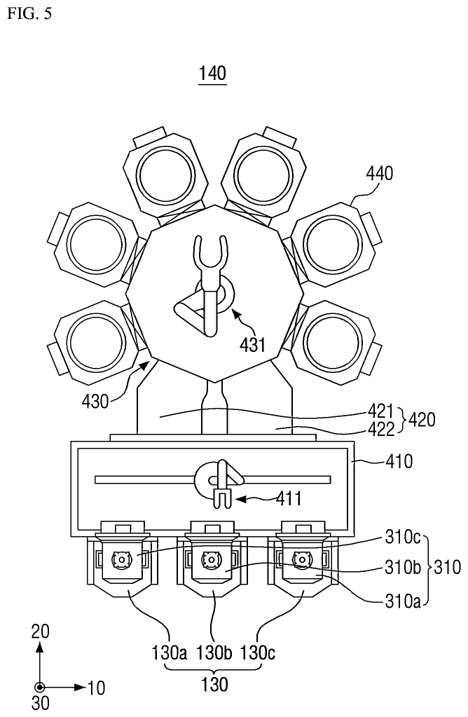

FIG. 5 illustrates an exemplary layout of the load port unit and the semiconductor fabrication equipment 140.

Referring to FIG. 5, the semiconductor fabrication equipment 140 may include an index module 410, load lock chambers 420, a transfer chamber 430, and process chambers 440.

The semiconductor fabrication equipment 140 may be a system for processing semiconductor substrates by performing various processes such as deposition, etching, cleaning, and heat treatment. The semiconductor fabrication equipment 140 may be implemented as a multi-chamber substrate processing system including first and second transport robots 411 and 431 and a plurality of process chambers 440, which are substrate processing modules and are provided around the first and second transport robots 411 and 431.

As already mentioned above, the load port unit 130 is provided to load thereon containers 310 with a plurality of semiconductor substrates loaded therein. The load port unit 130 may include a plurality of load ports, which are disposed at the front of the index module 410. For example, three load port units, i.e., first, second, and third load ports 130a, 130b, and 130c, may be disposed at the front of the index module 410.

When there are multiple load ports at the front of the index module 410, the containers 310, which are to be loaded on the multiple load ports, may load different types of objects. For example, when there are three load ports at the front of the index module 410, i.e., the first, second, and third load ports 130a, 130b, and 130c, a first container 310a, which is to be loaded on the first load port 130a, may load wafer-type sensors therein, a second container 310b, which is to be loaded on the second load port 130b, may load substrates (or wafers) therein, and a third container 310c, which is to be loaded on the third load port 130c, may load consumables such as focus rings therein.

However, the present disclosure is not limited to this example. Alternatively, the first, second, and third containers 310a, 310b, and 310c, which are to be loaded on the first, second, and third load ports 130a, 130b, and 130c, respectively, may load objects of the same type therein. Alternatively, some of the first, second, and third containers 310a, 310b, and 310c may load objects of the same type therein, and some of the first, second, and third containers 310a, 310b, and 310c may load objects of a different type from the rest of the first, second, and third containers 310a, 310b, and 310c.

The index module 410 may be disposed between the load port unit 130 and the load lock chambers 420 and may function as an interface to transport semiconductor substrates between the containers 310 and the load lock chambers 420. The index module 410 may be provided as an FEM.

The index module 410 may include the first transport robot 411, which is for transporting substrates. The first transport robot 411 may operate in an atmospheric pressure environment and may transfer semiconductor substrates between the containers 310 and the load lock chambers 420.

The load lock chambers 420 may function as buffers between input and output ports of the semiconductor fabrication equipment 140. Although not specifically illustrated in FIG. 5, the load lock chambers 420 may include buffer stages where semiconductor substrates temporarily stand by.

A plurality of load lock chambers 420 may be provided between the index module 410 and the transfer chamber 430. For example, two load lock chambers 420, i.e., first and second load lock chambers 421 and 422, may be provided between the index module 410 and the transfer chamber 430.

The first and second load lock chambers 421 and 422 may be arranged in a first direction 10 between the index module 410 and the transfer chamber 430. In this case, the first and second load lock chambers 421 and 422 may be provided in a mutually symmetric single-layer structure where they are arranged side-by-side in a left-to-right direction. The first direction 10 is a direction perpendicular, on a plane, to a second direction 20, which is the direction in which the index module 410 and the transfer chamber 430 are arranged.

However, the present disclosure is not limited to this. Alternatively, the first and second load lock chambers 421 and 422 may be arranged in a third direction 30 between the index module 410 and the transfer chamber 430. In this case, the first and second load lock chambers 421 and 422 may be provided in a double-layer structure where they are arranged vertically. The third direction 30 is a direction perpendicular to both the first and second directions 10 and 20.

The first load lock chamber 421 may transfer semiconductor substrates from the index module 410 to the transfer chamber 430, and the second load lock chamber 422 may transfer the semiconductor substrates from the transfer chamber 430 to the index module 410. However, the present disclosure is not limited to this. Alternatively, the first load lock chamber 421 may transfer semiconductor substrates from the transfer chamber 430 to the index module 410 and from the index module 410 to the transfer chamber 430, and the second load lock chamber 422 may also transfer semiconductor substrates from the transfer chamber 430 to the index module 410 and from the index module 410 to the transfer chamber 430.

Semiconductor substrates may be loaded in, or unloaded from, the load lock chambers 420 by the second transport robot 431 of the transfer chamber 430. Semiconductor substrates may also be loaded in, or unloaded from, the load lock chambers 420 by the first transport robot 411 of the index module 410.

The load lock chambers 420 may maintain the pressure by changing the environment therein into a vacuum environment or an atmospheric pressure environment via a gate valve. The load lock chambers 420 may prevent changes in the state of the atmospheric pressure in the transfer chamber 430.

Specifically, when substrates are loaded or unloaded by the second transport robot 431, the inside of the load lock chambers 420 may be transformed into the same vacuum environment as (or a similar vacuum environment to) the transfer chamber 430. Also, when substrates are loaded or unloaded by the first transport robot 411 (i.e., when substrates yet to be processed are provided from the first transport robot 5411 or substrates that have already been processed are delivered to the index module 410), the inside of the load lock chambers 420 may be transformed into an atmospheric pressure environment.

The transfer chamber 430 transfers substrates between the load lock chambers 420 and the process chambers 440. The transfer chamber 430 may be provided with at least one second transport robot 431.

The second transport robot 431 may transfer substrates yet to be processed from the load lock chambers 420 to the process chambers 440 and may transfer substrates that have already been processed from the process chambers 440 to the load lock chambers 420. The sides of the transfer chamber 430 may be connected to the load lock chambers 420 and the process chambers 440. The second transport robot 431 may operate in a vacuum environment and may be freely rotatable.

The process chambers 440 process substrates. A plurality of process chambers 440 may be disposed along the circumference of the transfer chamber 430. In this case, the process chambers 440 may receive semiconductor substrates from the transfer chamber 430, may process the semiconductor substrates, and may provide the processed semiconductor substrates to the transfer chambers 430.

The process chambers 440 may be formed into a cylindrical shape. The surfaces of the process chambers 440 may be formed of alumite, which is an anode oxide, and the inside of the process chambers 440 may be airtight. Alternatively, the process chambers 440 may have various shapes other than a cylindrical shape.

The semiconductor fabrication equipment 140 may be formed to have a cluster platform structure. In this case, the process chambers 440 may be arranged in a cluster manner around the transfer chamber 430, and the load lock chambers 420 may be arranged side-by-side in the first direction 10.

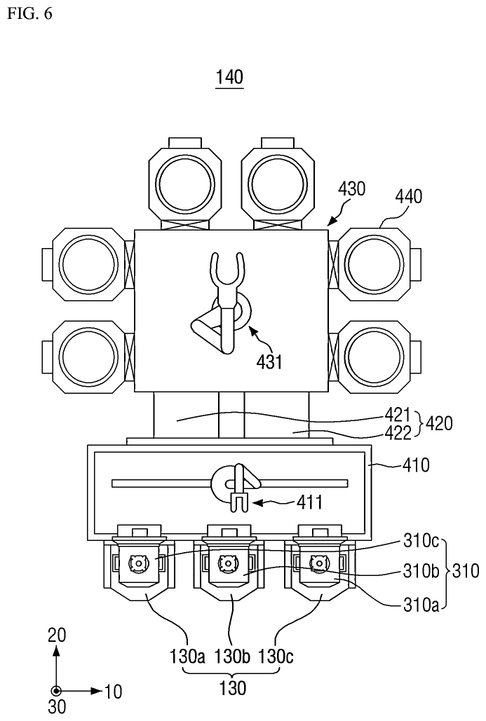

However, the present disclosure is not limited to this. Alternatively, referring to FIG. 6, the semiconductor fabrication equipment 140 may be formed to have a quad platform structure. In this case, the process chambers 440 may be arranged in a quad manner around the transfer chamber 430. FIG. 6 illustrates another exemplary layout of the load port unit 130 and the semiconductor fabrication equipment 140.

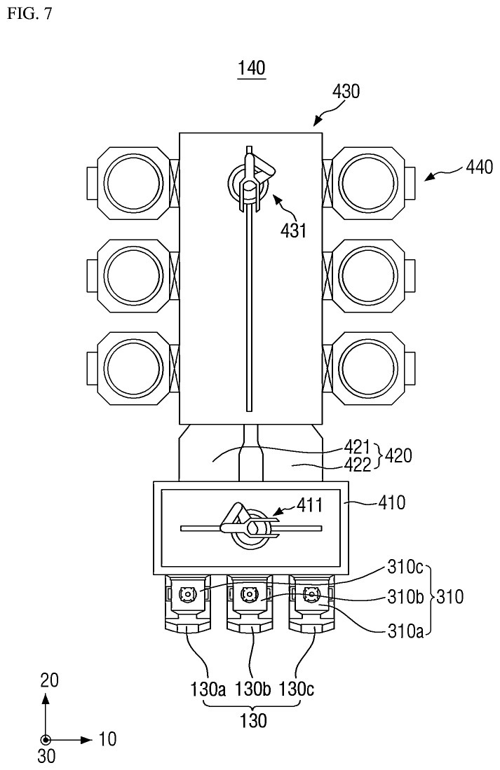

Alternatively, referring to FIG. 7, the semiconductor fabrication equipment 140 may be formed to have an in-line platform structure. In this case, the process chambers 440 may be arranged in an in-line manner around the transfer chamber 430. Pairs of process chambers 440 may be arranged in series on either side of the transfer chamber 430. FIG. 7 illustrates another exemplary layout of the load port unit 130 and the semiconductor fabrication equipment 140.

Referring again to FIGS. 1 and 2, the control unit 150 controls the general operations of the elements of the logistics transport system 100. The control unit 160 may control the operation of the container transport unit 110 through communication with, for example, the control module 260 and may also control the operations of the container relay unit 120 and the semiconductor fabrication equipment 140.

The control unit 150 may include a process controller, a control program, an input module, an output module (or a display module), and a memory module and may be implemented as a computer or a server. Here, the process controller may include a microprocessor executing a control function for each of the elements of the logistics transport system 100, the control program may execute various processes to be performed by the logistics transport system 100, under the control of the process controller, and the memory module may store programs (i.e., process recipes) for executing the various processes to be performed by the logistics transport system 100.

The container relay unit 120 may relay containers 310 between the container transport unit 110 and the load port unit 130. Typically, the container relay unit 120 is not provided in the logistics transport system 100, and the container transport unit 110 delivers the containers 310 directly to the load port unit 130. As already mentioned above, if problems arise in the process of delivering the containers 310 from the container transport unit 110 to the load port unit 130, the container transport unit 110 may not move to a subsequent destination, but may stand by until the delivery of the containers 310 is complete.

For example, if the load port unit 130 is already loaded with containers 310, the container transport unit 110 cannot deliver its containers 310 to the load port unit 130, but needs to stand by until the delivery of the containers 310 currently loaded in the load port unit 130 is complete.

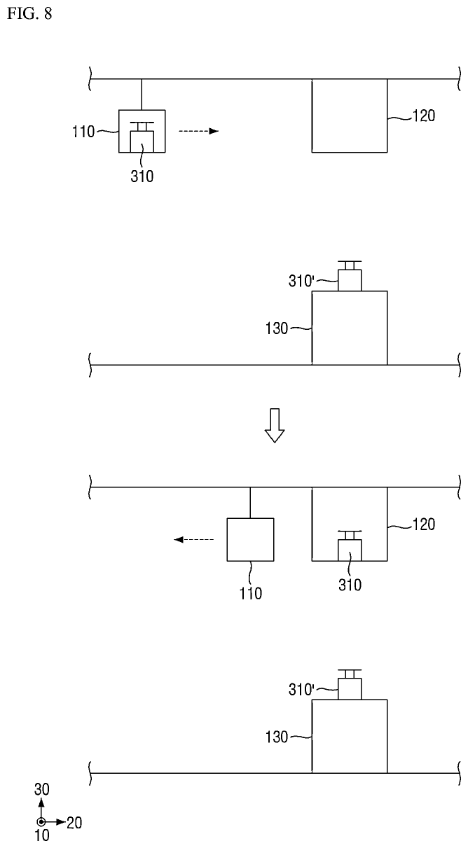

In the embodiment of FIGS. 1 and 2, the container relay unit 120 may be provided in the logistics transport system 100 and may relay containers 310 between the container transport unit 110 and the load port unit 130. In this case, referring to FIG. 8, even if the load port unit 130 is already loaded with containers 310, the container transport unit 110 may deliver its containers 310 to the container relay unit 120 and may then readily move to a subsequent destination. Accordingly, as the container relay unit 120 is provided in the logistics transport system 100, the takt time in the semiconductor fabrication plant 1000 can be reduced. FIG. 8 illustrates the benefits of the logistics transport system 100 with the container relay unit 120 provided therein.

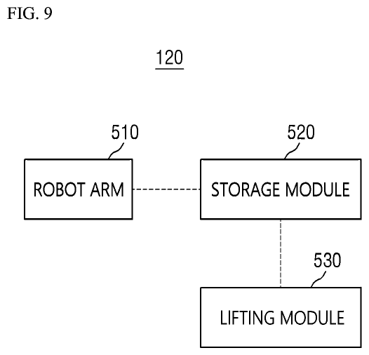

The container relay unit 120 may include a robot arm 510, a storage module 520, and a lifting module 530 to relay containers 310 between the container transport unit 110 and the load port unit 130. FIG. 9 illustrates the inner structure of the container relay unit 120 of the logistics transport system 100.

Referring to FIG. 9, the robot arm 510 handles a container 310 being gripped by the container transport unit 110. The container transport unit 110 may approach the container relay unit 120 to be able to deliver containers 310 to the load port unit 130. Then, the robot arm 510 may receive containers 310 from the container transport unit 110 and may store the containers 310 in the storage module 520.

The storage module 520 stores containers 310. The storage module 520 may have space in which to accommodate containers 310. At least one storage module 520 may be provided in the container relay unit 120.

The lifting module 530 transports the containers 310 stored in the storage module 520 to the load port unit 130. The lifting module 530 may transport the containers 310 in the vertical direction (i.e., in the third direction 30) and may also transport the containers 310 in a diagonal direction.

When the robot arm 510 handles a container 310 being gripped by the container transport unit 110, the lifting module 530 may handle the corresponding container 310 from the robot arm 510. The robot arm 510 may move in the second direction 20 to receive the container 310 from the container transport unit 110, and the lifting module 530 may move in the third direction 30 to relay the container 310 to the load port unit 130. That is, the robot arm 510 and the lifting module 530 may operate in different directions.

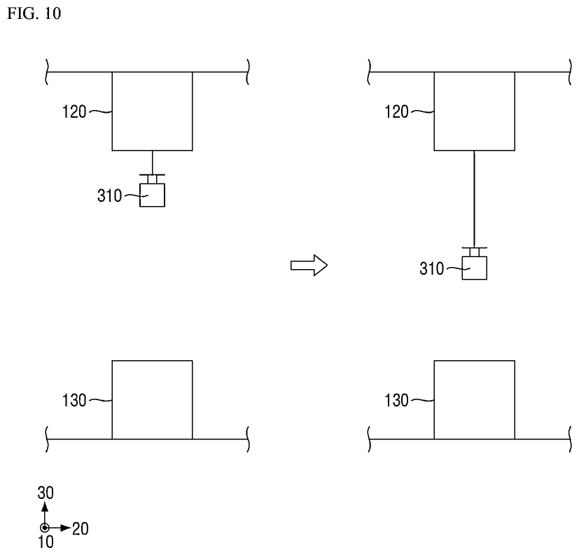

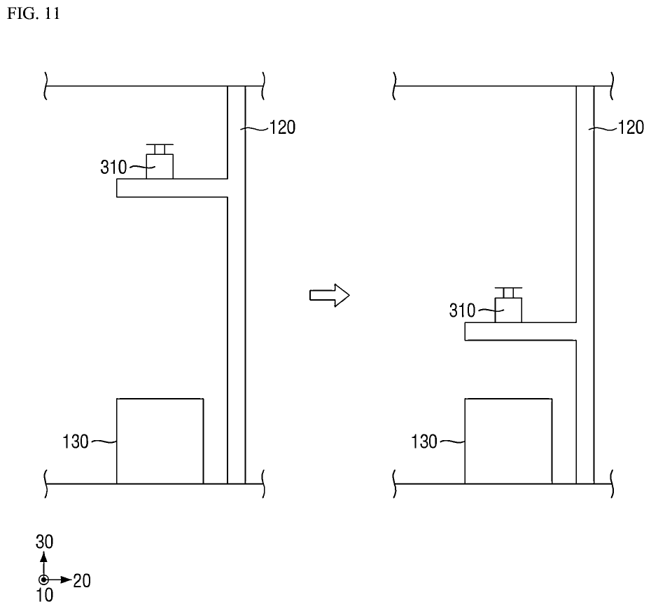

Referring to FIG. 10, the lifting module 530 may be provided as a host delivering a container 310 to the load port unit 130 while gripping the container 310, but the present disclosure is not limited thereto. Alternatively, referring to FIG. 11, the lifting module 530 may be provided as a lift delivering a container 310 to the load port unit 130 by operating like an elevator with the container 310 loaded thereon. FIG. 10 illustrates an exemplary lifting module 530 of the container relay unit 120, and FIG. 11 illustrates another exemplary lifting module 530 of the container relay unit 120.

Alternatively, a robot arm may be provided in the container transport unit 110 and may hand over containers 310 to the container relay unit 120. In this case, the container relay unit 120 may not include the robot arm 510, but may include only the storage module 520 and the lifting module 530.

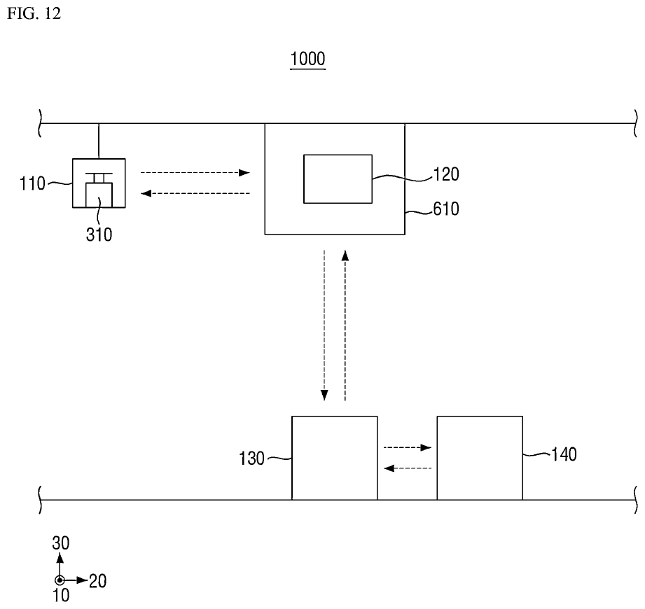

Alternatively, the container relay unit 120 may deliver containers 310 to the load port unit 130 as soon as the containers 310 are handed over from the container transport unit 110. In this case, the container relay unit 120 may not include the storage module 520, but may include only the robot arm 510 and the lifting module 530 or only the lifting module 530. Referring to FIG. 12, a side track buffer (STB) may be provided at the ceiling of the semiconductor fabrication plant 1000, and the container relay unit 120 may be installed in the STB. FIG. 12 illustrates another exemplary layout of the elements of the logistics transport system 100.

The STB 610 may be installed on a side of the moving path of the container transport unit 110 (e.g., the rails 330a and 330b) and may store containers 310. That is, the STB 610 may perform the same functions as a stocker provided at the ground in the semiconductor fabrication plant 1000 and may be provided at the ceiling of the semiconductor fabrication plant 1000. In this case, the container relay unit 120 may not include the storage module 520, but may include only the robot arm 510 and the lifting module 530.

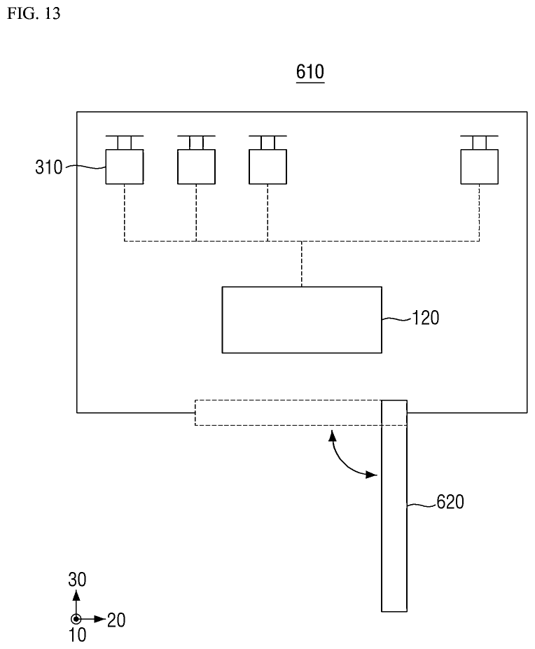

In a case where the container relay unit 120 is provided in the STB 610, the STB 610 may be provided above the load port unit 130 in the vertical direction (i.e., in the third direction 30), but the present disclosure is not limited thereto. Alternatively, if the container relay unit 120 can deliver containers 310 to the load port unit 130 in a diagonal direction, the STB 610 may not necessarily be provided above the load port unit 130 in the vertical direction. Referring to FIG. 13, in a case where the container relay unit 120 is provided in the STB 610, the STB may include a door 620 that can be opened or closed, in order for the container relay unit 120 to deliver containers 130 to the load port unit 130.

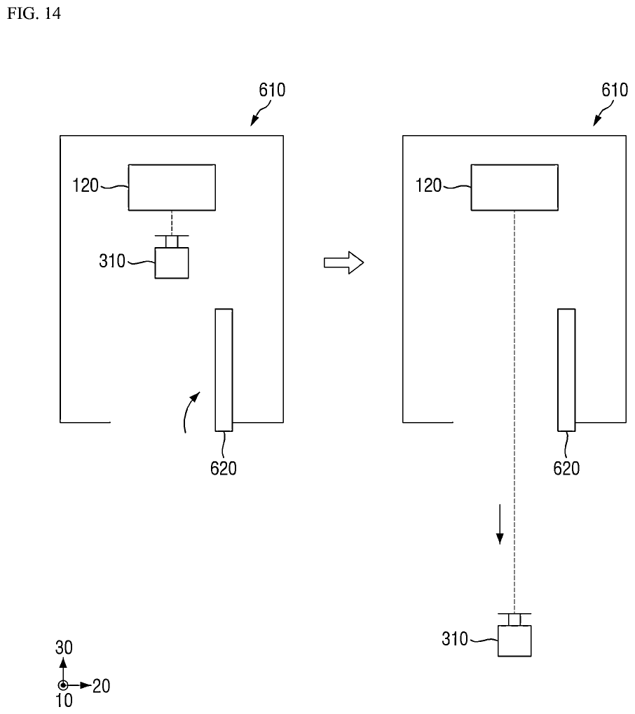

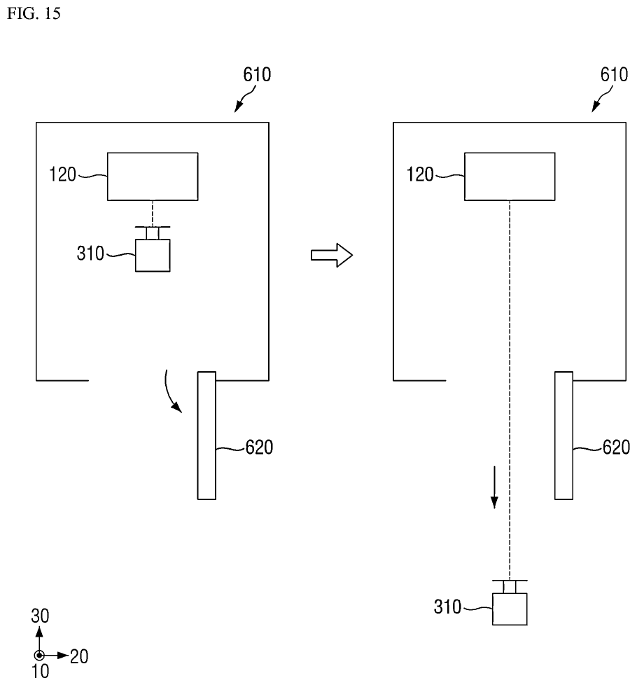

Referring to FIGS. 14 and 15, the door 620 may be opened or closed when the container relay unit 120 delivers containers 310 to the load port unit 130. FIG. 14 illustrates that the door 620 is opened toward the inside of the STB 610, and FIG. 15 illustrates that the door 620 is opened toward the outside of the STB 610. Specifically, FIG. 13 illustrates the inner structure of the STB 610 of the logistics transport system 100, FIG. 14 illustrates an exemplary operating principle of the door 620 of the STB 610, and FIG. 15 illustrates another exemplary operating principle of the door 620 of the STB 610.

In a case where the container relay unit 120 is not installed in the STB 610 and includes the storage module 520, the door 620 may also be applicable to the container relay unit 120 in order for the container relay unit 120 to be able to relay containers 310 to the load port unit 130. That is, the container relay unit 120 may include a lower door that perform the same functions as the door 620 of the STB 610.

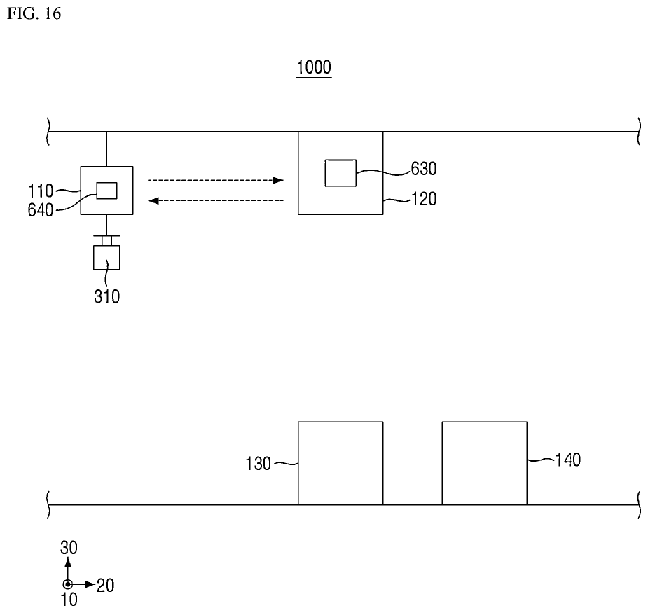

It will hereinafter be described how to detect and handle malfunction of the container relay unit 120. FIG. 16 illustrates another exemplary layout of the elements of the logistics transport system 100.

Referring to FIG. 16, the container transport unit 110 and the container relay unit 120 may communicate with each other. To this end, the container transport unit 110 may include a second communication module 640, and the container relay unit 120 may include a first communication module 630. The container transport unit 110 may determine, through communication with the container relay unit 120, whether the container relay unit 120 is able to relay containers 310 to the load port unit 130.

For example, the container transport unit 110 and the container relay unit 120 may communicate with each other in a parallel input/output (PIO) method. The container transport unit 110 may send a request message to the container relay unit 120. Then, if no response message is received from the container relay unit 120 for a predetermined amount of time, the container transport unit 110 may determine that the container relay unit 120 is not able to relay containers 310 to the load port unit 130.

If the container relay unit 120 is determined as not being able to relay containers 310 to the load port unit 130, the container transport unit 110 may deliver containers 310 directly to the load port unit 130. The container transport unit 110 may communicate with the container relay unit 120 when approaching the container relay unit 120, within a predetermined distance of the container relay unit 120.

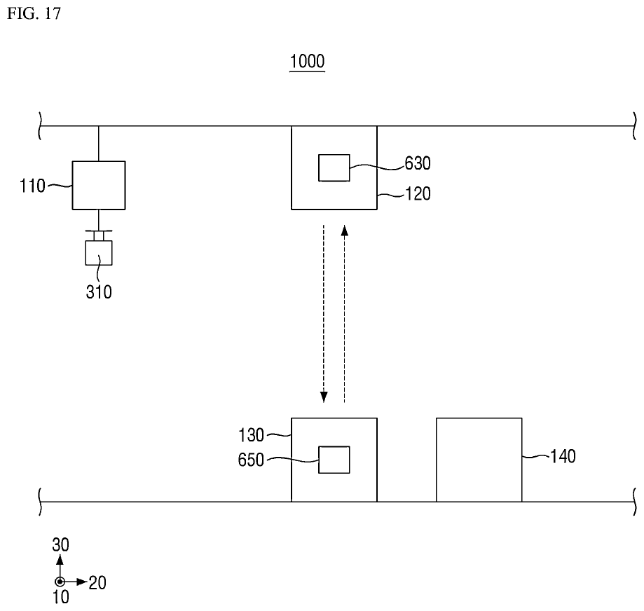

FIG. 16 illustrates that the container transport unit 110 determines whether the container relay unit 120 is malfunctioning through communication with the container relay unit 120, but the present disclosure is not limited thereto. Alternatively, referring to FIG. 17, a third communication module 650 may be installed in the load port unit 130, and the load port unit 130 may determine whether the container relay unit 120 is malfunctioning through communication with the container relay unit 120. FIG. 17 illustrates another exemplary layout of the elements of the logistics transport system 100.

Once the container transport unit 110 picks up containers 310 loaded with substrates that have already been processed from the load port unit 130, the load port unit 130 may communicate with the container relay unit 120 to determine whether the container relay unit 120 is able to relay containers 310 to the load port unit 130, before the container transport unit 110 arrives and delivers containers 310 loaded with substrates yet to be processed. The container relay unit 120 and the load port unit 130 may also communicate with each other in the PIO method.

If the container relay unit 120 is determined as not being able to relay containers 310 to the load port unit 130, the load port unit 130 may send a request for the delivery of containers 310 to the container transport unit 110 through the control unit 150.

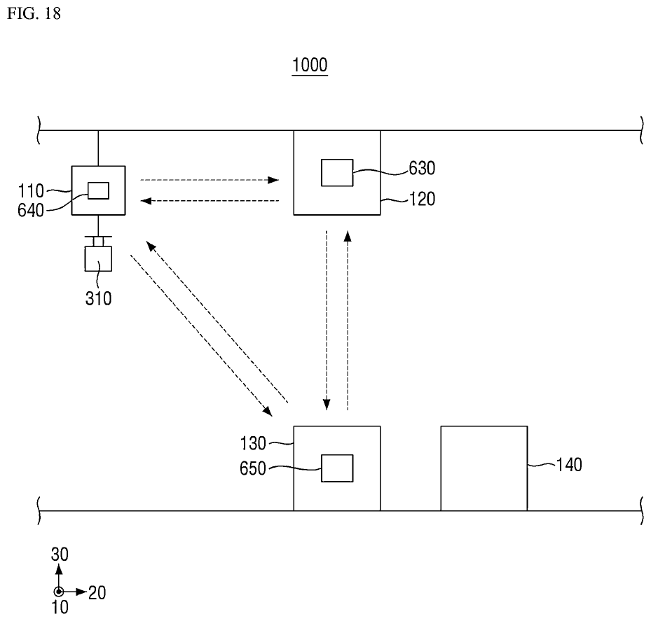

Referring to FIG. 18, the container transport unit 110, the container relay unit 120, and the load port unit 130 may include communication modules 630, 640, and 650, respectively, and the container transport unit 110 and the load port unit 130 may determine whether the container relay unit 120 is able to relay containers 310 through communication with the container relay unit 120. FIG. 18 illustrates another exemplary layout of the elements of the logistics transport system 100.

For example, the load port unit 130 may communicate with a plurality of container transport units 110, and if one of the container transport units 110 is determined as approaching the load port unit 130 to deliver containers 310, the load port unit 130 may communicate with the container relay unit 120 to determine whether the container relay unit 120 is able to relay the containers to the load port unit 130.

In some embodiments, the control unit 150 may determine whether the container relay unit 120 is able to relay containers 310 to the load port unit 130 through communication with the container relay unit 120. Alternatively, in some embodiments, the control unit 150 may determine whether the container relay unit 120 is able to relay containers 310 to the load port unit 130 based on the result of communication between the container transport unit 110 and the container relay unit 120. Alternatively, in some embodiments, the control unit 150 may determine whether the container relay unit 120 is able to relay containers 310 to the load port unit 130 based on the result of communication between the container relay unit 120 and the load port unit 130. Alternatively, in some embodiments, the control unit 150 may determine whether the container relay unit 120 is able to relay containers 310 to the load port unit 130 based on the result of communication between, the container transport unit 110, the container relay unit 120, and the load port unit 130.

The present disclosure relates to the logistics transport system 100 including the container relay unit 120, which is installed around the load port unit 130. When the container transport unit 110 arrives near the load port unit 130 while gripping or accommodating containers 310, the container relay unit 120 relays the containers 310 between the container transport unit 110 and the load port unit 130.

The container relay unit 120, which is an interface lift between an STB port and an equipment (EQ) port, can transport objects between the STB port and the EQ port and can thus reduce the takt time at the EQ port. Conventionally, the EQ port cannot be installed on the same line as the EQ port in a vertical direction, but the container relay unit 120 can overcome this limitation and can thus maximize the installation of the STB port.

The present disclosure relates to adding a vertical saddle lift capable of functioning as an interface between an STB port and equipment. The present disclosure can improve the efficiency of transportation between the STB port and an EQ port and can maximize the installation of the STB port.

Embodiments of the present disclosure have been described above with reference to the accompanying drawings, but the present disclosure is not limited thereto and may be implemented in various different forms. It will be understood that the present disclosure can be implemented in other specific forms without changing the technical concept or gist of the present disclosure. Therefore, it should be understood that the embodiments set forth herein are illustrative in all respects and not limiting.

What is claimed is:

1. A logistics transport system comprising:
a container transport unit installed in a semiconductor fabrication plant, the container transport unit transporting containers loaded with semiconductor substrates;
a load port unit where the containers are loaded or unloaded;
semiconductor fabrication equipment connected to the load port unit, the semiconductor fabrication equipment processing the semiconductor substrates loaded in the containers; and
a container relay unit relaying the containers between the container transport unit and the load port unit,
wherein the container relay unit is installed on the same level as a moving path of the container transport unit, on a level above the load port unit.

2. The logistics transport system of claim 1, wherein the container relay unit includes a lifting module, which delivers the containers received from the container transport unit to the load port unit.

3. The logistics transport system of claim 2, wherein
the lifting module receives the containers from the container transport unit, or
the container relay unit further includes a robot arm, which picks up the containers from the container transport unit.

4. The logistics transport system of claim 3, wherein if the container relay unit further includes the robot arm, moving directions of the robot arm and the lifting module are different.

5. The logistics transport system of claim 2, wherein the container relay unit further includes a storage module, which temporarily stores the containers.

6. The logistics transport system of claim 2, wherein the lifting module delivers the containers to the load port unit with the containers gripped or stored.

7. The logistics transport system of claim 1, further comprising:
a side track buffer (STB) storing the containers,
wherein the container relay unit is installed in the STB.

8. The logistics transport system of claim 7, wherein the STB is installed on a level including the level above the load port unit.

9. The logistics transport system of claim 7, wherein the STB includes a door that can be opened in a direction toward the load port unit.

10. The logistics transport system of claim 9, wherein the door is opened when the containers are delivered to the load port unit.

11. The logistics transport system of claim 1, wherein the container relay unit includes a door that can be opened in a direction toward the load port unit.

12. The logistics transport system of claim 1, wherein the container relay unit communicates with at least one of the container transport unit and the load port unit.

13. The logistics transport system of claim 12, wherein the at least one of the container transport unit and the load port unit determines whether the container relay unit is able to relay the containers, based on a result of the communication with the container relay unit.

14. The logistics transport system of claim 13, wherein if the container relay unit is determined as not being able to relay the containers, the container transport unit delivers the containers directly to the load port unit.

15. The logistics transport system of claim 12, wherein the container relay unit communicates with the at least one of the container transport unit and the load port unit in a parallel input/output (PIO) method.

16. The logistics transport system of claim 1, further comprising:
a control unit controlling operations of the container transport unit, the container relay unit, the load port unit, and the semiconductor fabrication equipment.

17. The logistics transport system of claim 16, wherein the container unit determines whether the container relay unit is able to relay the containers, based on a result of communication with at least one of the container transport unit and the load port unit.

18. A logistics transport system comprising:
a container transport unit installed in a semiconductor fabrication plant, the container transport unit transporting containers loaded with semiconductor substrates;
a load port unit where the containers are loaded or unloaded;
semiconductor fabrication equipment connected to the load port unit, the semiconductor fabrication equipment processing the semiconductor substrates loaded in the container; and
a container relay unit relaying the containers between the container transport unit and the load port unit,
wherein
the container relay unit includes a robot arm, which picks up the containers from the container transport unit, a storage module, which temporarily stores the containers, and a lifting module, which delivers the containers to the load port unit,
the container relay unit is installed on the same level as a moving path of the container transport unit, on a level above the load port unit,
the container relay unit communicates with at least one of the container transport unit and the load port unit, and
if the container relay unit is able to relay the containers, the container transport unit delivers the containers directly to the load port unit.

19. A container relay unit relaying containers between a container transport unit, which transports containers loaded with semiconductor substrates, in a semiconductor fabrication plant, and a load port unit where the containers are loaded or unloaded, the container relay unit comprising:
a robot arm picking up the containers from the container transport unit;
a storage module temporarily storing the containers; and
a lifting module delivering the containers to the load port unit.

20. The container relay unit of claim 19, wherein the container relay unit is installed on the same level as a moving path of the container transport unit, on a level above the load port unit.
